(19) United States
(12) Patent Application Publication
(10) Pub. No.: US 2025/0201758 A1
(43) Pub. Date: Jun. 19, 2025

(54) MOUNTING DEVICE

(71) Applicant: TORAY ENGINEERING CO., LTD., Tokyo (JP)

(72) Inventors: Shimpei AOKI, Otsu-shi (JP); Takashi HARE, Otsu-shi (JP); Kentaro MIHARA, Otsu-shi (JP)

(21) Appl. No.: 19/067,243

(22) Filed: Feb. 28, 2025

Related U.S. Application Data
(63) Continuation of application No. PCT/JP2023/030848, filed on Aug. 28, 2023.

(30) Foreign Application Priority Data
Sep. 13, 2022 (JP) 2022-144947

(51) Int. Cl. H01L 23/00; B23K 3/08; B23K 37/04; B23K 101/40

(52) U.S. Cl. CPC H01L 24/75; B23K 3/08; B23K 37/0408; B23K 2101/40; H01L 2224/75753; H01L 2224/75804

(57) ABSTRACT

A mounting device comprises an attachment tool configured to hold a surface of a chip component opposite to a surface having a chip recognition mark, a substrate stage configured to holds a substrate, a reflection light source configured to irradiate light containing wavelengths that pass through the chip component from the attachment tool side toward the substrate, and a recognition unit configured to recognize reflected light of the light irradiated by the reflection light source, the recognition unit being configured to acquire an image formed by light that passes through the chip component and is reflected by the substrate, to acquire position information of the substrate recognition mark.

### CROSS-REFERENCE TO RELATED APPLICATIONS

This application is a continuation application of PCT International Application No. PCT/JP2023/030848 filed on Aug. 28, 2023, which claims priority to Japanese Patent Application No. 2022-144947 filed on Sep. 13, 2022 with Japan Patent Office. The entire disclosures of PCT International Application No. PCT/JP2023/030848 and Japanese Patent Application No. 2022-144947 are hereby incorporated herein by reference.

### BACKGROUND

### Field of the Invention

The present invention relates to a mounting device for mounting chip components on a substrate. In particular, the present invention relates to a mounting device for mounting the electrode surface of a chip component facing the electrode surface of a substrate.

### Background Information

One form for mounting a semiconductor chip or other such chip component on a wiring substrate or other such substrate is face-down mounting, in which the electrode surface of the chip component is mounted facing the electrode surface of the substrate.

### SUMMARY

FIG. 13 shows an example of a substrate S for performing face-down mounting, in which a chip component is bonded to each of a plurality of mounting locations SC arranged on the substrate S, with the electrode surfaces facing each other. At this time, unless the chip components are accurately placed in each of the mounting locations SC of the substrate S, the electrical connection between the substrate S and the chip components will be incomplete, resulting in poor quality of the semiconductor device. Therefore, a first substrate recognition mark AS1 and a second substrate recognition mark AS2 are provided as substrate recognition marks AS on the electrode surface side of each mounting location SC of the substrate S, as shown in FIG. 13. On the other hand, a first chip recognition mark AC1 and a second chip recognition mark AC2 are provided as chip recognition marks AC on the electrode surface of the chip components, and, in the state shown in FIG. 14, the relative position of the chip component C (in the in-plane direction of the substrate S) with respect to the mounting location SC of the substrate S is determined from the positional relationship between the first substrate recognition mark AS1 and the first chip recognition mark AC1 as well as the positional relationship between the second substrate recognition mark AS2 and the second chip recognition mark AC2, which can be corrected to improve positional accuracy.

An upper and lower two-field camera 500a, such as shown in FIG. 15, can be used when determining the relative positions of the chip recognition marks AC and the substrate recognition marks AS, and imaging can be performed with the first chip recognition mark AC1 (or the second chip recognition mark AC2) placed in the field of view of an upper field 50U of the upper and lower two-field camera 500a and the first substrate recognition mark AS1 (or the second substrate recognition mark AS2) placed in the field of view of a lower field 50D.

By using this upper and lower two-field camera 500a to achieve and correct the relative position of the chip component C (in the in-plane direction of the substrate S) with respect to the mounting location SC of the substrate S, it becomes possible to perform mounting with a maximum error of several μm.

In face-down mounting, or so-called flip chip mounting, a maximum error of several μm is sufficient when the electrode pitch is 100 μm or more, such as when solder bumps are used as the electrodes of the chip component C, but the margin becomes tight when the electrode pitch is just over 50 μm, such as when Cu pillar bumps are used, and, as mounting density increases further and the electrode pitch becomes smaller, there are now applications for which the accuracy is insufficient.

Therefore, an upper and lower two-field camera can be used to further improve accuracy. On the other hand, it has been discovered that in the state shown in FIG. 15, even if the chip component C is aligned with an error of less than 1 μm (in the in-plane direction of the substrate S) with respect to the mounting location SC of the substrate S, the maximum error at the mounting stage may exceed 1 μm. It has also been discovered that this is because when the chip C is lowered from the state shown in FIG. 15 toward the substrate S, there is a slight tilt in the direction of descent. If resolution is attempted by increasing the machining accuracy and rigidity of each component of the mounting device such that the direction of descent becomes perpendicular to the surface that holds the substrate S, then this has an impact on the cost of the device. In addition, in an upper and lower two-field camera, it is difficult to align the optical axes of the upper and lower cameras, resulting in occurrence of relative misalignment, so it becomes necessary to correct the relative misalignment.

Therefore, in order to increase the accuracy of face-down mounting without greatly affecting the cost of the device, inventors of the present disclosure has combined an aligning method used in face-up mounting and found a method by which alignment can be carried out in a state in which chip components are brought as close as possible to the substrate.

With this method, as shown in FIGS. 16A and 16B, tool recognition marks are appended on an attachment tool 42 that holds the chip component C, and alignment is performed via this tool recognition marks. Specifically, a chip position recognition means 8 images a first chip recognition mark AC1 and a first tool recognition mark AT1 in the same field of view in the state shown in FIG. 16A to obtain relative position information, and similarly obtains the relative position information of a second chip recognition mark AC2 and a second tool recognition mark AT2 in the state shown in FIG. 16B. Then, as shown in FIG. 17A, the chip position recognition means 8 obtains the positional relationship between the first tool recognition mark AT1 and the first substrate recognition mark AS1 in a state in which the chip component C is brought close to the substrate S, obtains the positional relationship between the second tool recognition mark AT2 and the second substrate recognition mark AS2 as shown in FIG. 17B, and then aligns the relative positions of the chip component C and the substrate S. In this method, because the alignment uses images captured with one camera, there is no problem of relative misalignment that occurs with an upper and lower two-field camera.

On the other hand, it is conceivable that mounting locations SC are arranged on the substrate S with small gaps therebetween, as shown in FIG. 18. In such a case, unlike the case in which the substrate recognition marks AS are on the outer sides of the mounting locations SC, as shown in FIG. 13, the substrate recognition marks AS are provided within the mounting locations SC, as shown in FIG. 19, so at the mounting stage, the substrate recognition marks AS are covered by the chip components C.

As a result, in this case, the substrate recognition marks AS cannot be observed when performing alignment in the state as shown in FIGS. 17A and 17B.

In the field of wafer bonding, there is a technique in which wafers are aligned using light (such as near-infrared light) having wavelengths that pass through silicon (see Japanese Laid Open Patent Application Publication No. 2018-093140, for example). FIGS. 20, 21A, 21B and 21C illustrate schematic drawings explaining an alignment when bonding silicon wafers together with a device according to a comparative example shown in FIG. 20. With the device shown in FIG. 20, as shown in FIG. 21C, a lower wafer recognition mark AWB shown in FIG. 21A and an upper wafer recognition mark AWT shown in FIG. 21B are observed, by observing, with a recognition means 501a (which is sensitive to near-infrared light), near-infrared light emitted from a transmission light source 702.

The inventors of the present disclosure has conceived of applying the wafer bonding technique to a device shown in FIG. 22 to mount chip components C on a substrate S. However, it has been discovered that it is difficult to apply the wafer bonding technique to the device shown in FIG. 22 because internal wiring CW present inside the substrate S blocks the near-infrared light, making it difficult to identify the substrate recognition marks AS (and chip recognition marks AC). In addition, it has also been discovered that since a heater is often build into the substrate stage that holds the substrate, it is also difficult to install the light source below the heater.

One object of the present disclosure is to provide a mounting device that acquires position information of a substrate recognition mark even when a chip component covers the substrate recognition mark to achieve highly-accurate mounting, in face-down mounting in which electrode surfaces are mounted facing each other.

In order to solve the problem described above, according to a first aspect of the present disclosure, a mounting device is configured to mount a chip component having a chip recognition mark for alignment and a substrate having a substrate recognition mark for alignment such that a surface having the chip recognition mark faces a surface having the substrate recognition mark, in a state in which the substrate recognition mark is covered by the chip component. The mounting device comprises an attachment tool configured to hold a surface of the chip component opposite to the surface having the chip recognition mark, a substrate stage configured to hold the substrate, a reflection light source configured to irradiate light containing wavelengths that pass through the chip component from the attachment tool side toward the substrate, and a recognition unit configured to recognize reflected light of the light irradiated by the reflection light source, the recognition unit being configured to acquire an image formed by light that passes through the chip component and is reflected by the substrate, to acquire position information of the substrate recognition mark.

According to a second aspect, with the mounting device according to the first aspect, the recognition unit is configured to acquire an image formed by light that is irradiated from the reflection light source, passes through the chip component and is reflected by the surface of the chip component having the chip recognition mark, to acquire position information of the chip recognition mark, and the position information of the substrate recognition mark and the position information of the chip recognition mark are used to align the substrate and the chip.

According to a third aspect, the mounting device according to the first aspect further comprises a transmission light source configured to irradiate light containing wavelengths that pass through the chip component toward the chip component from below the chip component, the recognition unit being configured to acquire an image formed by light that is irradiated from the transmission light source and has wavelengths that pass through the chip component, to acquire position information of the chip recognition mark, and the position information of the substrate recognition mark and the position information of the chip recognition mark being used to align the substrate and the chip.

According to a fourth aspect, with the mounting device according to the third aspect, the recognition unit is configured to acquire the position information of the chip recognition mark, after which the attachment tool is moved toward the substrate stage, and the position information of the substrate recognition mark is acquired in a state in which the chip component is brought close to the substrate such that the substrate recognition mark is within a depth of field of the recognition unit.

According to a fifth aspect, with the mounting device according to the fourth aspect, a relative position of the recognition unit with respect to the attachment tool is maintained after the position information of the chip recognition mark is acquired until the position information of the substrate recognition mark is acquired.

According to a sixth aspect, the mounting device according to the first aspect further comprises a transmission light source configured to irradiate light containing wavelengths that pass through the chip component toward the chip component from below the chip component, the attachment tool having a tool recognition mark, the recognition unit being configured to acquire position information of the chip recognition mark and position information of the tool recognition mark from an image formed by light that is irradiated from the transmission light source and has wavelengths that pass through the chip component and the attachment tool, after which the recognition unit is configured to acquire position information of the substrate recognition mark and position information of the tool recognition mark from an image formed by light that is irradiated from the reflection light source and is reflected by the substrate, and has wavelengths that pass through the chip component and the attachment tool, and relative position information with the tool recognition mark is used to obtain a positional relationship between the substrate recognition mark and the chip recognition mark, to align the substrate and the chip.

According to a seventh aspect, with the mounting device according to the sixth aspect, the position information of the substrate recognition mark and the position information of the tool recognition mark are acquired in a state in which the chip component is brought close to the substrate such that both the substrate recognition mark and the tool recognition mark are within a depth of field of the recognition unit.

The present disclosure provides a mounting device that acquires position information of a substrate recognition mark even when a chip component covers the substrate recognition mark to achieve highly-accurate mounting, in face-down mounting in which electrode surfaces are mounted facing each other.

### BRIEF DESCRIPTION OF THE DRAWINGS

FIG. 1 is a schematic diagram of a mounting device according to an embodiment of the present disclosure.

FIGS. 2A and 2B are diagrams explaining an optical configuration according to the embodiment of the present disclosure, with FIG. 2A showing a front view of the optical configuration, and FIG. 2B showing a side view of the optical configuration.

FIG. 3 is a block diagram showing a control system according to the embodiment of the present disclosure.

FIGS. 4A and 4B are diagrams showing states in which a recognition means of the mounting device according to the embodiment of the present disclosure, with FIG. 4A showing a state for acquiring position information of a first substrate recognition mark, and FIG. 4B showing a state for acquiring position information of a second substrate recognition mark.

FIG. 5 is a schematic diagram of a mounting device according to a first modified example of the embodiment of the present disclosure.

FIGS. 6A and 6B are diagrams showing states in which a recognition means of the mounting device according to the first modified example of the embodiment of the present disclosure, with FIG. 6A showing a state for acquiring position information of a first chip recognition mark, and FIG. 6B showing a state for acquiring position information of a second chip recognition mark.

FIG. 7 is a schematic diagram of a mounting device according to a second modified example of the embodiment of the present disclosure.

FIGS. 8A and 8B are diagrams showing states in which a recognition means of the mounting device according to the second modified example of the embodiment of the present disclosure, with FIG. 8A showing a state for acquiring position information of a first chip recognition mark and position information of a first tool recognition mark, and FIG. 8B showing a state for acquiring position information of a second chip recognition mark and position information of a second tool recognition mark.

FIGS. 9A and 9B are diagrams showing states in which the recognition means of the mounting device according to the second modified example of the embodiment of the present disclosure, with FIG. 9A showing a state for acquiring position information of a first substrate recognition mark and position information of a first tool recognition mark, and FIG. 9B showing a state for acquiring position information of a second substrate recognition mark and position information of a second tool recognition mark.

FIGS. 10A and 10B are diagrams of a mounting device according to a third modified example of the embodiment of the present disclosure, in which an image capture unit is disposed for each combination of a substrate recognition mark and a chip recognition mark, with FIG. 10A showing a state for acquiring position information of a chip recognition mark, and FIG. 10B showing a state for acquiring position information of a substrate recognition mark.

FIGS. 11A and 11B are diagrams of a mounting device according to a fourth modified example of the embodiment of the present disclosure, in which an image capture unit having a field of view that can capture a plurality of combinations of substrate recognition marks and chip recognition marks is disposed, with FIG. 11A showing a state for acquiring position information of a chip recognition mark, and FIG. 11B showing a state for acquiring position information of a substrate recognition mark.

FIGS. 12A and 12B are diagrams of a mounting device according to a fifth modified example of the embodiment of the present disclosure, in which a mounting head picks up chips from a chip supply unit, with FIG. 12A showing a state in which a chip component is picked up, FIG. 12B showing a state for acquiring position information of a chip recognition mark, and FIG. 12C showing a state for acquiring position information of a substrate recognition mark.

FIG. 13 is a diagram explaining a substrate on which a plurality of chip components are mounted, mounting locations in which the chip components are mounted, and each of the substrate recognition marks.

FIG. 14 is a diagram showing a state in which chip recognition marks and substrate recognition marks face each other when mounting a chip component on a substrate.

FIG. 15 is a diagram showing an example in which alignment is performed with chip recognition marks of a chip component and a substrate recognition mark of a substrate facing each other.

FIGS. 16A and 16B are diagrams showing an example in which high-precision alignment is performed, with FIG. 16A showing a state in which a chip position recognition means acquires position information of a first chip recognition mark and position information of a first tool recognition mark, and FIG. 16B showing a state in which the chip position recognition means acquires position information of a second chip recognition mark and position information of a second tool recognition mark.

FIGS. 17A and 17B are diagrams showing an example in which high-precision alignment is performed, with FIG. 17A showing a state in which a recognition means acquires position information of a first substrate recognition mark and position information of a first tool recognition mark, and FIG. 17B showing a state in which the recognition means acquires position information of a second substrate recognition mark and position information of a second tool recognition mark.

FIG. 18 is a diagram explaining a substrate on which a plurality of chip components are mounted with small gaps therebetween, mounting locations in which the chip components are mounted, and each of the substrate recognition marks.

FIG. 19 is a diagram showing a state in which chip recognition marks and substrate recognition marks face each other when mounting a plurality of chip components with small gaps therebetween.

FIG. 20 is a diagram explaining alignment using near-infrared light transmission used in wafer bonding.

FIGS. 21A, 21B and 21C are diagrams showing recognition marks used for alignment in wafer bonding, with FIG. 21A showing an example of the shape of a lower wafer recognition mark, FIG. 21B showing an example of the shape of an upper wafer recognition mark, and FIG. 21C showing a transmitted image of the upper and lower wafer recognition marks in a state in which alignment has been achieved.

FIG. 22 is a diagram explaining a case in which alignment using near-infrared light transmission is applied to mounting of a chip component on a substrate having internal wiring.

### DETAILED DESCRIPTION OF EMBODIMENTS

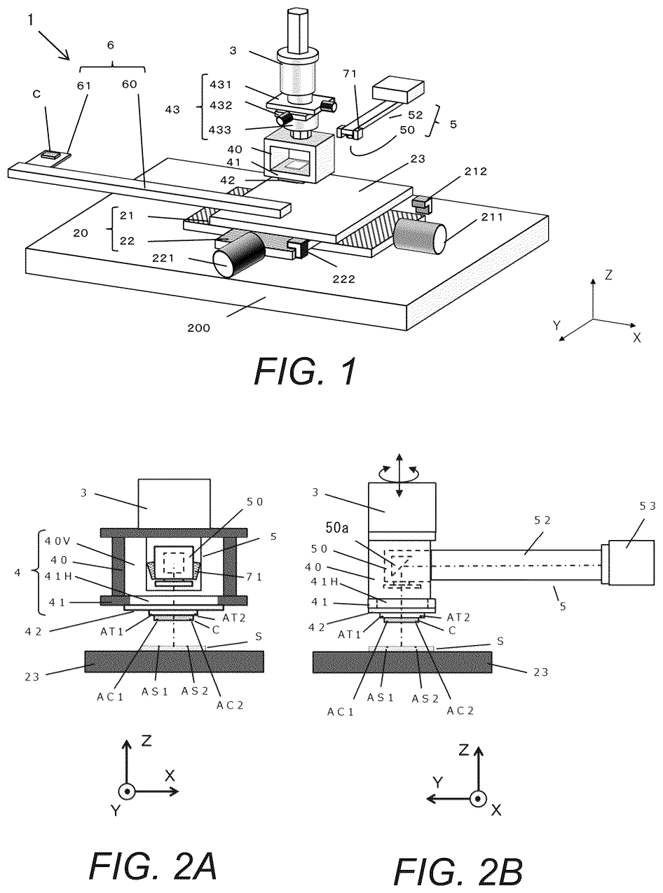

Selected embodiments of the present disclosure will be described below with reference to the drawings. FIG. 1 is a schematic diagram of a mounting device 1 according to an embodiment of the present disclosure.

A mounting device mounts chip components on a substrate, such as a wiring substrate, and the mounting device 1 of FIG. 1 is configured to perform face-down mounting, in which mounting is performed with the electrode surface of the chip component and the electrode surface of the substrate facing each other.

The constituent elements of the mounting device 1 include a substrate stage 2, an elevating means or unit 3, a mounting head 4, a recognition means or unit (mechanism) 5, a chip conveyance means or unit 6, and a light source 7 with at least one reflection light source 71 and/or at least one transmission light source 72.

In the mounting device 1 shown in FIG. 1, the substrate stage 2 is composed of a stage movement control means or unit 20 and a suction table 23. The suction table 23 uses suction to hold a substrate placed on the surface thereof, and the suction table 23 can be moved by the stage movement control means 20 in the in-plane direction of the substrate surface, while holding the substrate.

The stage movement control means 20 is composed of a Y-direction stage movement control means or unit 22 that is capable of moving the suction table 23 linearly in the Y direction, and an X-direction stage movement control means or unit 21 that is provided on a base 200 and is capable of moving the Y-direction stage movement control means 22 linearly in the X direction. The Y-direction stage movement control means 22 has a movable part that is disposed on a slide rail and on which the suction table 23 is mounted, and the movement and position of the movable part are controlled by a Y-direction servo 221. The X-direction stage movement control means 21 has a movable part that is disposed on a slide rail and on which the Y-direction stage movement control means 22 is mounted, and the movement and position of the movable part are controlled by an X-direction servo 211.

The elevating means 3 is fixed to a gate-shaped frame (not shown) and has a vertical drive shaft provided perpendicular to the suction table 23, and the mounting head 4 is connected to the vertical drive shaft. The elevating means 3 has a function of driving the mounting head 4 up and down, and of applying pressure in accordance with a setting. In addition, with the mounting device 1, the elevating means 3 is supported from two directions (by a gate-shaped frame (not shown)), and is linked linearly to the mounting head 4, so lateral force is less likely to be applied to the mounting head 4 during pressure application. In the illustrated embodiment, the elevating means or unit 3 includes an electronic actuator or motor (i.e., an elevation actuator or motor) that drives the vertical drive shaft to drive the mounting head 4 up and down.

The mounting head 4 holds and pressure-bonds the chip component C parallel to the substrate (which is held by the suction table 23 of the substrate stage 2). The constituent elements of the mounting head 4 include a head body 40, a heater unit or heater 41, an attachment tool 42, and a tool position control means or unit 43. The head body 40 is linked to the elevating means 3 via the tool position control means 43, and the heater unit 41 is disposed and fixed on the lower side thereof. The heater unit 41 has a heat generating function, and heats the chip component C through the attachment tool 42. In addition, the heater unit 41 has a function of using suction to hold the attachment tool 42, using a reduced-pressure channel. The attachment tool 42 uses suction to hold the chip component C, and is replaced to match the shape of the chip component C. The tool position control means 43 finely adjusts the position of the head body 40 in the in-plane direction perpendicular to the vertical drive shaft of the elevating means 3, and the positions of the attachment tool 42 and the chip component C held by the attachment tool 42 (within the XY plane in the drawings) are adjusted accordingly. In the illustrated embodiment, the tool position control means 43 includes one or more electronic actuators or motors, for example.

The constituent elements of the tool position control means 43 include the electronic actuators that form an X-direction tool position control means or unit 431, a Y-direction tool position control means or unit 432, and a tool rotation control means or unit 433, respectively. In the embodiment shown in FIG. 1, the configuration is such that the tool rotation control means 433 adjusts the rotation direction of the head body 40, the Y-direction tool position control means 432 adjusts the Y-direction position of the tool rotation control means 433, and the X-direction tool position control means 431 adjusts the X-direction position of the Y-direction position control means 432, but the present invention is not limited thereto; the tool rotation control means 433 may be disposed above (on the elevating means 3 side) the X-direction tool position control means 431, so long as the X-direction position, the Y-direction position, and the rotation angle of the attachment tool 42 can be adjusted.

FIGS. 2A and 2B mainly shows the periphery of the head body 40 (FIG. 2A is a front view, and FIG. 2B is a side view), but in the face-down mounting of the present embodiment, chip recognition marks AC (first chip recognition mark AC1 and second chip recognition mark AC2) are provided at diagonally opposite locations of the electrode surface of the chip component C, and substrate recognition marks AS (first substrate recognition mark AS1 and second substrate recognition mark AS2) are provided at guide positions at diagonally opposite mounting locations of the chip component on the electrode surface of the substrate S. Here, the chip recognition marks AC and the substrate recognition marks AS preferably have the property of reflecting light having wavelengths that pass through (silicon, which is the material of) the chip component C, described further below.

The mounting device 1 is configured so that it is possible to observe the directions of the substrate recognition marks AS and the chip recognition marks AC through the mounting head 4, and either the attachment tool 42 has transparency with respect to light having wavelengths that pass through the chip component or through-holes are provided that are aligned with the positions of the substrate recognition marks AS. In addition, the heater unit 41 either must be made of a material allowing the substrate recognition marks AS to be observed or have an opening; in this embodiment, a through-hole 41H is provided, as shown in FIGS. 2A and 2B. In addition, it is desirable to carry out image capture at a plurality of locations (for each combination of a substrate recognition mark AS and a chip recognition mark AC) to obtain, at a high resolution, position information of the substrate recognition marks AS and/or the chip recognition marks AC, which requires space in which an image capture unit 50 of the recognition means 5 can move; in the present embodiment, the mounting head 4 is provided with a head space 40V as shown in FIGS. 2A and 2B. That is, the head body 40 has a structure composed of side plates linked above the heater unit 41 and a top plate linking the two side plates.

The recognition means 5 is sensitive to light having wavelengths that pass through the chip component C, and is able to image the substrate recognition marks AS and the chip recognition marks AC and obtain position information of the substrate recognition marks AS and the chip recognition marks from the arrangement position information of the recognition means 5 and coordinates within the field of view imaged by the recognition means 5. In the present embodiment, the constituent elements of the recognition means 5 include the image capture unit 50, an optical path 52, and an imaging means or unit 53 linked to the optical path 52. Here, the imaging means 53 is sensitive to light having wavelengths that pass through the chip component C. In the illustrated embodiment, the recognition means 5 includes a recognition mechanism. In the illustrated embodiment, the imaging means 53 includes an electronic image sensor, such as a charge-coupled device (CCD), an active-pixel sensor (CMOS sensor), and the like, for example.

The image capture unit 50 is disposed facing a recognition target from which the imaging means 53 acquires an image, and keeps the recognition target within the field of view. In the illustrated embodiment, the image capture unit 50 forms an objective, and includes an optical element, such as a lens or mirror, or combinations of several optical elements, for example. In the illustrated embodiment, the image capture unit 50 includes a reflecting means or unit 50a formed by a mirror or prism, for example.

Additionally, the recognition means 5 includes a drive mechanism, such as an electronic actuator or motor, to move the image capture unit 50 in the in-plane direction of the substrate S (and the chip component C) within the head space 40V. Preferably, movement in a direction perpendicular to the substrate S (Z direction) is also possible so that the focal position can be adjusted.

The mounting head 4 is moved perpendicular to the substrate S by the elevating means 3, and this operation can be performed independently of the operation of the recognition means 5. Therefore, the head space 40V must be designed to have dimensions such that the recognition means 5 entering the head space 40V will not interfere even if the mounting head 4 moves in the vertical direction.

The movable range of the image capture unit 50 of the recognition means 5 is not limited to within the head space 40V; it is also possible to move over the substrate S outside of the head space 40V to acquire position information of the substrate recognition marks AS.

The chip conveyance means 6 includes a conveyor that is formed by a conveyance rail 60 and a chip slider 61, and is configured so that the chip slider 61 holds and slides the chip component C supplied from a chip supply unit (not shown) to below the attachment tool 42.

Here, the chip supply unit places the chip component C at a set position on the chip slider 61. If necessary, the position where the chip component C is placed on the chip slider 61 may be recognized by a recognition mechanism (not shown). In addition, the chip conveyance means 6 may include a position adjustment means or unit that adjusts the in-plane-direction (XY direction) position of the chip component C placed on the chip slider 61. In this case, the position adjustment means includes an adjuster or an electronic actuator that adjust the in-plane-direction position of the chip component C. Thus, controlling the positions of the chip slider 61 and the chip component C placed on the chip slider 61 allows the chip component C to be transferred to within a prescribed range of the attachment tool 42. After the attachment tool 42 has held the chip component C, the chip slider 61, which has released the chip component C, moves to a retracted position.

In the illustrated embodiment, the reflection light source 71 is provided as the light source 7. In the illustrated embodiment, the reflection light source 71 is provided at two locations, but the reflection light source 71 is not limited to this number. The reflection light source 71 irradiates light from the upper side of the attachment tool 42 toward the substrate S, and the light emitted by the reflection light source contains wavelengths that pass through the chip component C. Here, the wavelengths that pass through the chip component C are preferably in the near-infrared region, but no limitation is imposed thereby. Thus, in the illustrated embodiment, the light source 7 or the reflection light source 71 includes a light emitting diode (LED) or a laser diode that operates in the infrared spectrum (e.g., infrared (IR) LEDs, etc.).

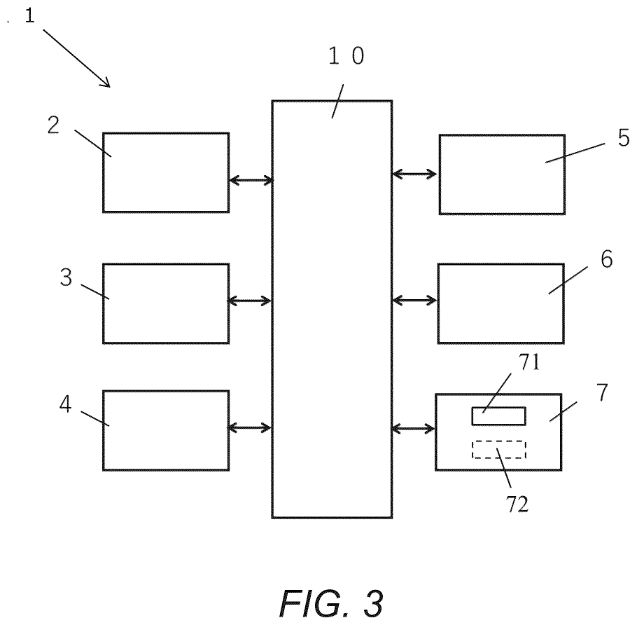

As shown in the block diagram of FIG. 3, the mounting device 1 further comprises a control unit or electronic controller 10 that is electrically and operatively connected to the substrate stage 2, the elevating means 3, the mounting head 4, the recognition means 5, the chip conveyance means 6, and the light source 7. Essentially, the main constituent elements of the control unit 10 shown in FIG. 3 includes at least one processor having a CPU (Central Processing Unit) and a storage device or computer memory, and an interface is provided between the devices as necessary. In addition, the control unit 10 can have a built-in program to perform calculations using acquired data and to output according to the calculation result. Furthermore, it is desirable for the control unit 10 to have the function of recording and using the acquired data and calculation result as data for new calculations.

The control unit 10 is connected to the substrate stage 2 and controls the operations of the X-direction stage movement control means 21 and the Y-direction stage movement control means 22, thereby controlling the in-plane movement of the suction table 23. In addition, the control unit 10 controls the suction table 23 to control the application and release of suction to and from the substrate S.

The control unit 10 is connected to the elevating means 3, controls the position of the mounting head 4 in the up and down direction (Z direction), and has the function of controlling the pressure applied when the chip component C is pressure-bonded to the substrate S.

The control unit 10 is connected to the mounting head 4, and has the function of controlling the application and release of suction to and from the chip component C by the attachment tool 42, the heating temperature of the heater unit 41, and the position within the XY plane of the head body 40 (and the heater unit 41 and the attachment tool 42), using the tool position control means 43.

The control unit 10 is connected to the recognition means 5, controls the position of the image capture unit 50 in the horizontal (in the XY plane) direction and the vertical direction (Z direction), and has a function of controlling the imaging means 53 to acquire image data. Furthermore, the control unit 10 has an image processing function, and has a function of calculating the relative positional relationship between the substrate recognition marks AS and the tool recognition marks AT from the position information of the image capture unit 50 and an image acquired by the imaging means 53, and, together with the position information of the image capture unit 50, calculating the positions of the substrate recognition marks AS and/or the tool recognition marks AT.

The control unit 10 is connected to the chip conveyance means 6, and has a function of controlling the position of the chip slider 61 that moves along the conveyance rail 60.

The control unit 10 is connected to the reflection light source 71, and has a function of controlling presence/absence of light irradiation and the irradiation power.

The steps by which the mounting device 1 aligns and mounts a chip component on a mounting location SC of the substrate S will be described below; prior to these steps, the substrate S undergoes a substrate holding step and is held by the substrate stage 2 of the mounting device 1. Here, it is preferable that information on the placement of the substrate S with respect to the suction table 23 of the substrate stage 2 has been acquired by an image recognition means, or the like, and stored in the control unit 10.

In addition, the chip component C has been conveyed by the chip conveyance means 6 and has undergone a chip holding step in which the chip component C is held by the attachment tool 42. Here, a prescribed level of positional accuracy is ensured when the chip component Cis handed over from the chip supply unit to the chip slider 61, and then handed over from the chip slider 61 to the attachment tool 42, and the chip component C is held by the attachment tool 42 with a prescribed level of positional accuracy.

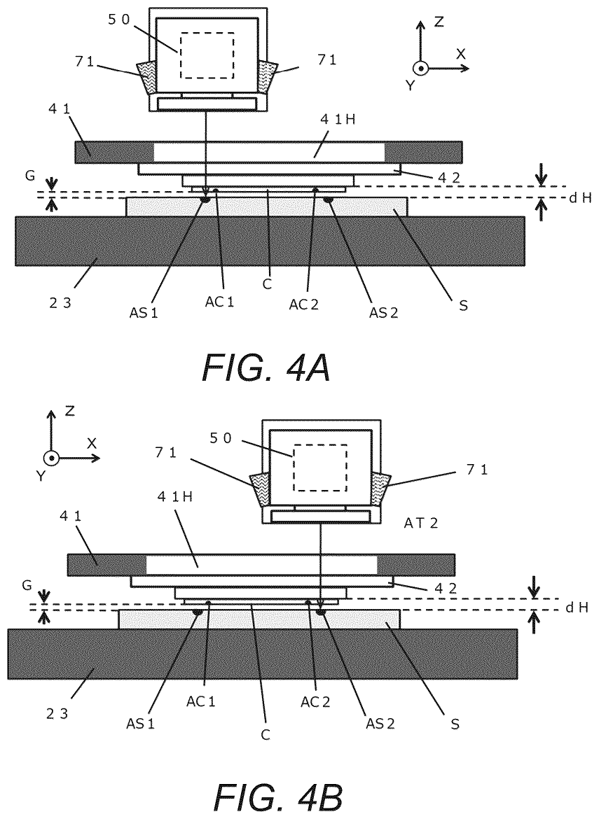

FIGS. 4A and 4B are diagrams explaining a substrate position acquisition step in which position information of the substrate recognition marks AS is acquired. In FIGS. 4A and 4B, the reflection light source 71 irradiates light containing wavelengths that pass through the chip component C. Therefore, in FIG. 4A, the recognition means 5 obtains an image formed by light that has wavelengths that pass through the chip component C and that is reflected on the surface of the substrate S and passes through the chip component C, and position information of the first substrate recognition mark AS1 is obtained or calculated from the image. In addition, by moving the recognition means 5 horizontally, position information of the second substrate recognition mark AS2 can be obtained or calculated (in the same manner as with the first substrate recognition mark AS1), as seen in FIG. 4B. With the steps described above, the arrangement state of (the mounting locations SC of) the substrate S can be obtained.

Here, there are cases in which position information of the chip recognition marks AC can be obtained in the state shown in FIGS. 4A and 4B. That is, in the case shown in FIG. 4A, a part of the light that enters inside the chip component C is reflected on the lower surface of the chip, but if the reflectance is different between the first chip recognition mark AC1 and the other parts, the first chip recognition mark AC1 can be observed simultaneously with the first substrate recognition mark AS1. In particular, in a state in which the chip component C is brought close to the substrate S, if both the first substrate recognition mark AS1 and the first chip recognition mark AC1 are observed within the depth of field, it is possible to acquire accurate position information of the first substrate recognition mark AS1 and the first chip recognition mark AC1. The same applies for the second chip recognition mark AC2 and the second substrate recognition mark AS2 in FIG. 4B, and it is possible to perform alignment from only the operations shown in FIGS. 4A and 4B.

However, compared to substrate recognition marks AS, chip recognition marks AC have low contrast due to, inter alia, the effect of insulating layers formed on the electrode surface of the chip component C which has the chip recognition marks AC, so identification may be difficult even when using image processing, and it may not be possible to acquire position information.

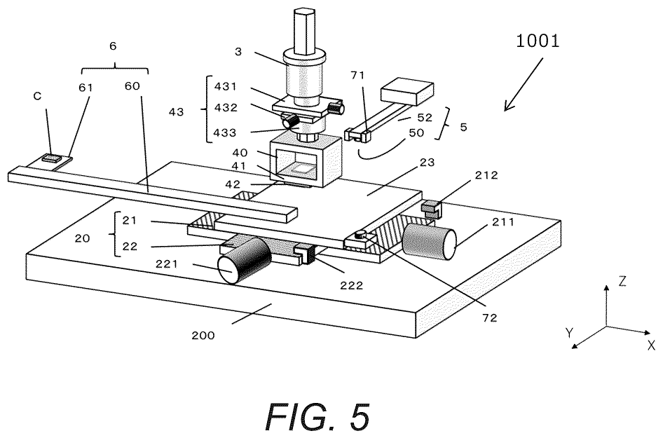

Even in such a case, it is necessary to obtain the position information of the chip recognition marks AC by another method. Therefore, as a first modified example of the mounting device 1, a decision was made to obtain the position information of the chip recognition marks AC using a mounting device 1001 having a device configuration as shown in FIG. 5. The difference in FIG. 5 with respect to the mounting device 1 shown in FIG. 1 is the presence of the transmission light source 72. Here, the transmission light source 72 emits light containing wavelengths that pass through chip components, similar to the reflection light source 71. In addition, the transmission light source 72 is connected to the control unit 10 and controlled by the control unit 10. Thus, in the illustrated embodiment, the light source 7 or the transmission light source 72 includes a light emitting diode (LED) or a laser diode that operates in the infrared spectrum (e.g., infrared (IR) LEDs, etc.). Hereinafter, the same configuration as in the above-mentioned embodiment is illustrated with the same symbol in the drawings and its explanation will be omitted.

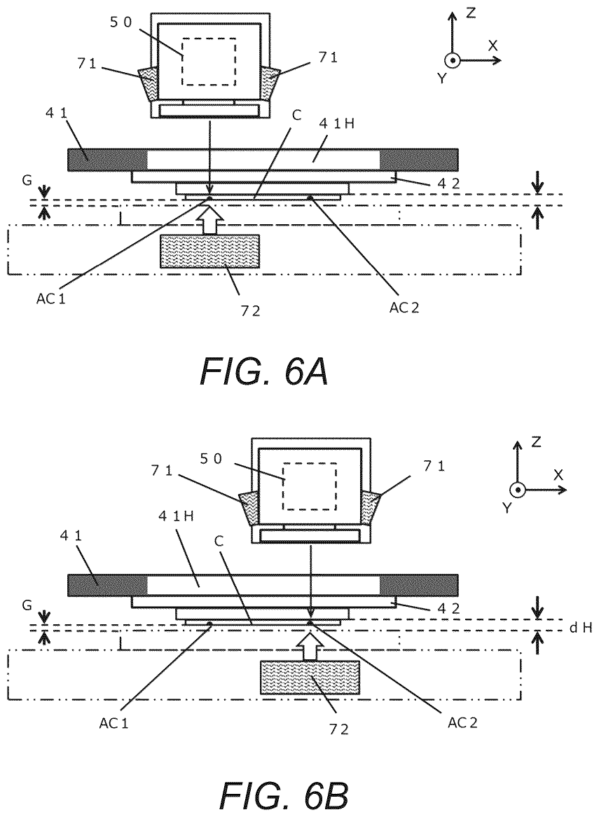

FIGS. 6A and 6B explain a method of acquiring position information of chip recognition marks using this transmission light source 72. In FIGS. 6A and 6B, the substrate S is retracted from under the chip component C, and the transmission light source 72 is disposed in its place. In this state, the height of the mounting head 4 is the same as in the state in which the chip component C is brought close to the substrate S, as shown in FIGS. 4A and 4B. In addition, when the recognition means 5 acquires an image, the reflection light source 71 is not turned on, and the transmission light source 72 irradiates light toward the chip component C.

In the state shown in FIG. 6A, the recognition means 5 can obtain, from the image capture unit 50, a clear image of the first chip recognition mark AC1 using light having wavelengths that pass through the chip component C, and can acquire, with the control unit 10 that has obtained the image information, the position information of the first chip recognition mark AC1. Similarly, position information of the second chip recognition mark AC2 can be acquired in the state shown in FIG. 6B.

Here, as described above, both FIGS. 4A and 4B and FIGS. 6A and 6B show states in which the chip component C is brought close to the substrate S, so the position information of the first substrate recognition mark AS1 and the first chip recognition mark AC1, and the position information of the second substrate recognition mark AS2 and the second chip recognition mark AC2 can be obtained under the same condition, so the amount of positional misalignment of the chip component C with respect to the mounting location SC of the substrate S can be calculated. Therefore, in order to correct this positional misalignment, positional adjustment is performed for the substrate stage 2 and/or the attachment tool 42 to align the chip component C with the mounting location SC, after which the mounting head 4 is lowered to bring the chip component C in close contact with the substrate S to perform mounting.

Incidentally, acquisition of the position information of the substrate recognition marks AS in the state shown in FIGS. 4A and 4B may be carried out before or after acquisition of the position information of the chip recognition marks AC shown in FIGS. 6A and 6B, but the substrate stage 2 needs to be moved in the horizontal direction, and the mounting head 4 may need to be moved up and down. Therefore, error occurs in the amount of positional misalignment of the chip component C with respect to the mounting location SC in accordance with the repeatability of the mechanisms for moving the substrate stage 2 and the mounting head 4, so highly-accurate alignment cannot be guaranteed. In addition, the substrate stage 2 needs to be moved by a relatively large amount, so the time required for this movement may affect the mounting takt time.

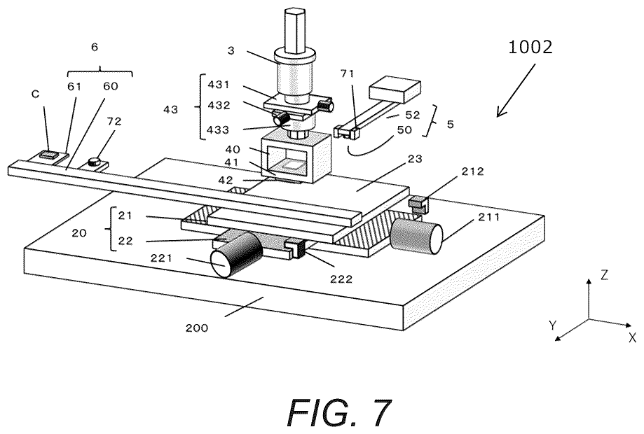

A second modified example of the mounting device 1 taking such situations into consideration is shown in FIG. 7. In a mounting device 1002 shown in FIG. 7, in a state in which the attachment tool 42 moves away from the substrate S and holds the chip component C handed over by the chip slider 61, the transmission light source 72 disposed between the substrate S and the chip component C irradiates light toward the chip component C.

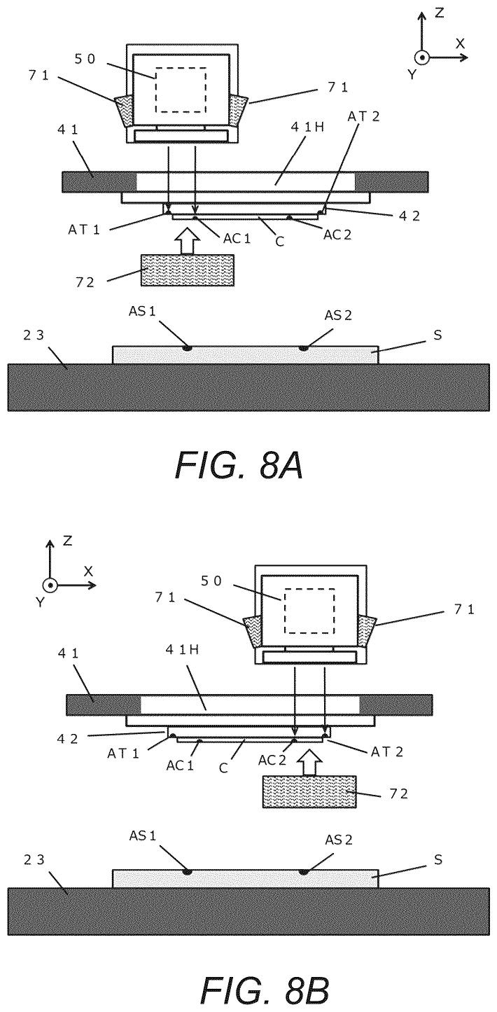

In the second modified example, the attachment tool 42 is provided with tool recognition marks AT, a specific state of which is shown in FIGS. 8A and 8B. Here, in a state in which the attachment tool 42 holds the chip component C, the first tool recognition mark AT1 and the second tool recognition mark AT2 are provided on the attachment tool 42 such that the first tool recognition mark AT1 is near the first chip recognition mark AC1, and the second tool recognition mark AT2 is near the second chip recognition mark AC2. The tool recognition marks AT are drawn using a material with low transmittance (and preferably also high reflectance) with respect to light having wavelengths that are included in the wavelengths of the transmission light source 72 and that pass through the chip component C.

In the state shown in FIG. 8A, the recognition means 5 can obtain, from the image capture unit 50, an image of the first chip recognition mark AC1 and the first tool recognition mark AT1 using light having wavelengths that pass through the chip component C and the attachment tool 42, and can acquire and store, with the control unit 10 that has obtained the image information, the relative position information of the first chip recognition mark AC1 and the first tool recognition mark AT1. Similarly, it is possible, in the state shown in FIG. 8B, to acquire and store the relative position information of the second chip recognition mark AC2 and the second tool recognition mark AT2. As a result, the position information of the first chip recognition mark AC1 and the second chip recognition mark AC2 can be calculated from the position information of the first tool recognition mark AT1 and the second tool recognition mark AT2.

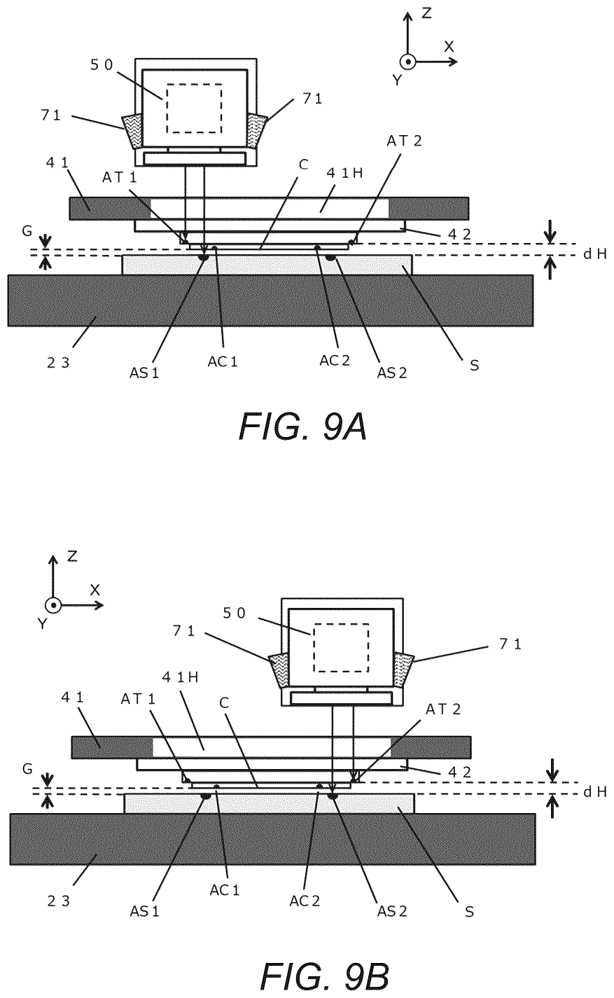

Next, the transmission light source 72 (and the chip slider 61) is retracted, the chip component C is brought as close as possible to, but without contacting, the substrate S, in the same manner as shown in FIGS. 4A and 4B, and the reflection light source 71 is used to acquire an image. FIGS. 9A and 9B show the foregoing state, but in FIGS. 9A and 9B, unlike in FIGS. 4A and 4B, the tool recognition marks AT are also observed in addition to the substrate recognition marks AS. In FIGS. 9A and 9B, it is desirable for the substrate recognition marks AS and the tool recognition marks AT to be within the depth of field of the recognition means 5.

In the state shown in FIG. 9A, the recognition means 5 can acquire, from the image capture unit 50, an image of the first substrate recognition mark AS1 and the first tool recognition mark AT1, and can acquire, with the control unit 10 that has obtained the image information, the relative position information of the first substrate recognition mark AS1 and the first tool recognition mark AT1; however, since the relative position information of the first chip recognition mark AC1 and the first tool recognition mark AT1 is obtained first, the position information of the first substrate recognition mark AS1 and the first chip recognition mark AC1 can be calculated. Similarly, it is possible to calculate the position information of the second substrate recognition mark AS2 and the second chip recognition mark AC2 from the observation made in the state shown in FIG. 9B.

In this manner, the position information of the first substrate recognition mark AS1 and the first chip recognition mark AC1 and the position information of the second substrate recognition mark AS2 and the second chip recognition mark AC2 can be obtained, and the amount of positional misalignment of the chip component C with respect to the mounting location SC of the substrate S can be calculated. Therefore, in order to correct this positional misalignment, positional adjustment is performed for the substrate stage 2 and/or the attachment tool 42 to align the chip component C with the mounting location SC, after which the mounting head 4 is lowered to bring the chip component C in close contact with the substrate S to perform mounting.

In this second modified example, the relative positional relationship between the chip recognition marks AC and the tool recognition marks AT is unrelated to the distance between the attachment tool 42 and the substrate S, and alignment can be performed in a state in which the chip component C is brought close to the substrate S, so mounting can be performed with highly-accurate alignment with few causes of error. In addition, the position information of the chip recognition marks AC and the tool recognition marks AT can be acquired at about the height at which the attachment tool 42 receives the chip component C from the chip slider 61, so the substrate stage 2 does not need to be operated, and the effect on the mounting takt time is minimal.

Incidentally, if the relative position of the image capture unit 50 with respect to the attachment tool 42 is the same as those shown in FIGS. 8A and 9A, images can be obtained at the same position with respect to the chip component C in FIGS. 8A and 9A. Therefore, the position information of the first chip recognition mark AC1 obtained and stored in the state shown in FIG. 8A and the position information of the first substrate recognition mark AS1 obtained in FIG. 9A can be compared in the same field of view and at the same coordinates. Therefore, the position information of the first tool recognition mark AT1 is not required. Similarly, if the relative position of the image capture unit 50 with respect to the attachment tool 42 is the same as those shown in FIGS. 8B and 9B, the position information of the second tool recognition mark AT2 is not required. However, in a device configuration in which one image capture unit 50 moves in the horizontal direction (XY plane) and the vertical direction (Z direction) to acquire the position information of each of the recognition marks, it is difficult to fully match the relative position of the image capture unit 50 with respect to the attachment tool 42 in FIGS. 8A and 9A (same applies to FIGS. 8B and 9B), so it is desirable to obtain the relative position information of the chip recognition marks AC and the substrate recognition marks AS via the tool recognition marks AT.

On the other hand, if the relative position of the image capture unit 50 is maintained (fixed) with respect to the attachment tool 42 after the position information of the chip recognition marks AC is acquired until the position information of the substrate recognition marks AS is acquired, precise alignment is possible without using the tool recognition marks AT.

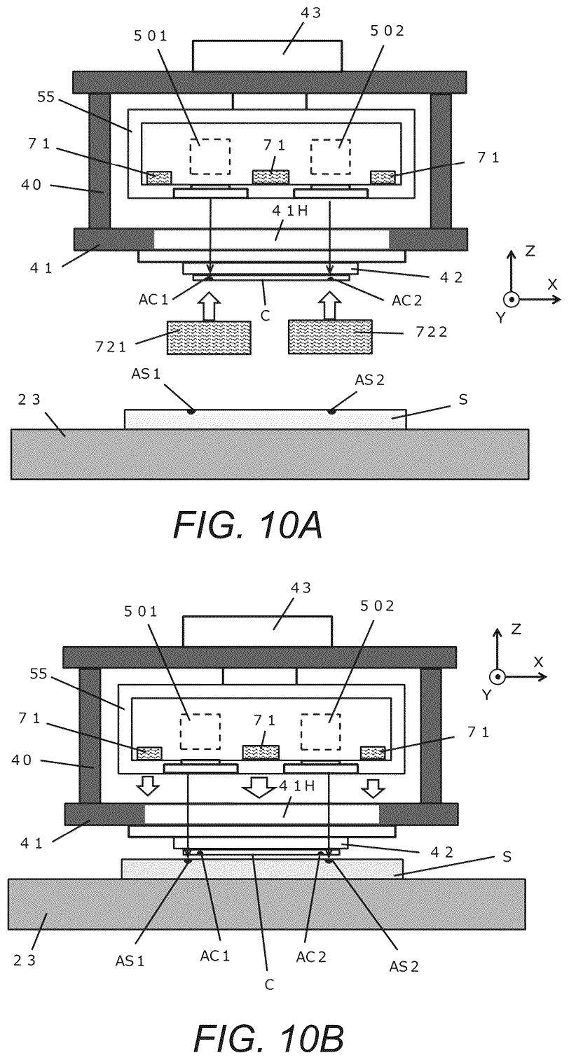

One example of such a configuration is the third modified example shown in FIGS. 10A and 10B. In the third modified example shown in FIGS. 10A and 10B, a recognition means or unit 55 includes an image capture unit 501 for acquiring the position information of the first chip recognition mark AC1 and the first substrate recognition mark AS1, and an image capture unit 502 for acquiring the position information of the second chip recognition mark AC2 and the second substrate recognition mark AS2. The image capture unit 501 and the image capture unit 502 are provided separately to the recognition means 55. The recognition means 55 further includes an optical path and an imaging means that are basically identical to the optical path 52 and the imaging means 53, respectively, for each of the image capture unit 501 and the image capture unit 502. In the state shown in FIG. 10A, a transmission light source 721 is turned on, and the imaging means corresponding to the image capture unit 501 obtains an image of the first chip recognition mark AC1 captured by the image capture unit 501. The imaging means corresponding to the image capture unit 501 is connected to the control unit 10, and, from the image, position information of the first chip recognition mark AC1 within the field of view of the imaging means can be calculated by computational processing of the control unit 10 and stored. Similarly, a transmission light source 722 is turned on, and the imaging means corresponding to the image capture unit 502 obtains an image of the second chip recognition mark AC2 captured by the image capture unit 502. The imaging means corresponding to the image capture unit 502 is connected to the control unit 10, and, from the image, position information of the second chip recognition mark AC2 within the field of view of the imaging means can be calculated by computational processing of the control unit 10 and stored.

FIG. 10B shows a state in which the transmission light source 721 and the transmission light source 722 are thereafter retracted, the relative positions of the image capture unit 501 and the image capture unit 502 are maintained (fixed) with respect to the head body 40 (and the attachment tool 42), and the chip component C is brought close to the substrate S. In the state shown in FIG. 10B, the reflection light source 71 is turned on, the imaging means corresponding to the image capture unit 501 obtains an image of the first substrate recognition mark AS1 captured by the image capture unit 501 using light having wavelengths that pass through the chip component C, and calculates, using the control unit 10, position information of the first substrate recognition mark AS1 within the field of view of the imaging means. Similarly, the imaging means corresponding to the image capture unit 502 obtains an image of the second substrate recognition mark AS2 captured by the image capture unit 502, and calculates, using the control unit 10, position information of the second substrate recognition mark AS2 within the field of view of the imaging means.

Thus, the positional misalignment (in the XY direction as well as the angle of rotation with respect to the Z direction) of the chip component C with respect to the substrate S can be calculated from the positional relationship between the first chip recognition mark AC1 and the first substrate recognition mark AS1 and the positional relationship between the second chip recognition mark AC2 and the second substrate recognition mark AS2, obtained from within the same field of view and at the same coordinates, and the position of the attachment tool 42 may be corrected by the tool position control means 43 so as to correct the positional misalignment.

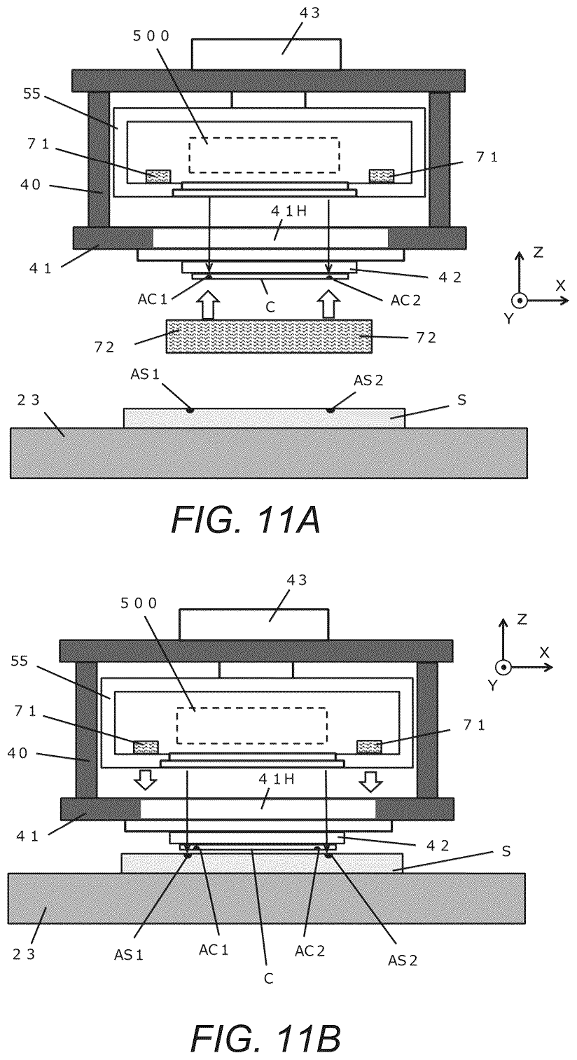

Meanwhile, in the third modified example, two imaging means are provided corresponding to the two separate image capture units 501 and 502. Specifically, the imaging means corresponding to the image capture unit 501 for obtaining position information of the first chip recognition mark AC1 and the first substrate recognition mark AS1, and the imaging means corresponding to the image capture unit 502 for obtaining position information of the second chip recognition mark AC2 and the second substrate recognition mark AS2 are separately provided. However, the number of imaging means or image capture units may be one as long as the position information of the first chip recognition mark AC1 and the first substrate recognition mark AS1 and position information of the second chip recognition mark AC2 and the second substrate recognition mark AS2 can be obtained with the accuracy required for alignment. That is, in a fourth modified example of the embodiment of the present disclosure, as shown in FIGS. 11A and 11B, a recognition means or unit 55 includes an image capture unit 500 for acquiring the position information of the first chip recognition mark AC1 and the first substrate recognition mark AS1, and for acquiring the position information of the second chip recognition mark AC2 and the second substrate recognition mark AS2. The recognition means 55 further includes an optical path and an imaging means that are basically identical to the optical path 52 and the imaging means 53 for the image capture unit 500. The transmission light source 72 is turned on in the state shown in FIG. 11A, the imaging means corresponding to the image capture unit 500 obtains an image of the first chip recognition mark AC1 and the second chip recognition mark AC2 captured by the image capture unit 500. The control unit 10 connected to the imaging means calculates and stores the position information of the first chip recognition mark AC1 and the second chip recognition mark AC2. FIG. 11B shows a state in which the transmission light source 72 is thereafter retracted, the relative position of the image capture unit 500 is maintained (fixed) with respect to the head body 40, and the chip component C is brought close to the substrate S. In the state shown in FIG. 11B, the reflection light source 71 is turned on, the imaging means corresponding to the image capture unit 500 obtains an image of the first substrate recognition mark AS1 and the second substrate recognition mark AS2 captured by the image capture unit 500 using light having wavelengths that pass through the chip component C. The control unit 10 calculates and stores the position information of the first substrate recognition mark AS1 and the second substrate recognition mark AS2 within the field of view of the imaging means corresponding to the image capture unit 500.

Next, the positional misalignment (in the XY direction as well as the angle of rotation with respect to the Z direction) of the chip component C with respect to the substrate S may be calculated from the positional relationship between the first chip recognition mark AC1 and the first substrate recognition mark AS1 and the positional relationship between the second chip recognition mark AC2 and the second substrate recognition mark AS2, obtained from within the same field of view and at the same coordinates, and the position of the attachment tool 42 may be adjusted by the tool position control means 43 so as to correct the positional misalignment.

As shown in FIGS. 10A and 10B and FIGS. 11A and 11B, as long as the relative position of the image capture unit 50 (500, 501, 502) of the recognition means 5 (55) is maintained (fixed) with respect to the attachment tool 42 after the position information of the chip recognition marks AC is acquired until the position information of the substrate recognition marks AS is acquired, the present disclosure can be implemented even with a device configuration in which the mounting head 4 moves significantly.

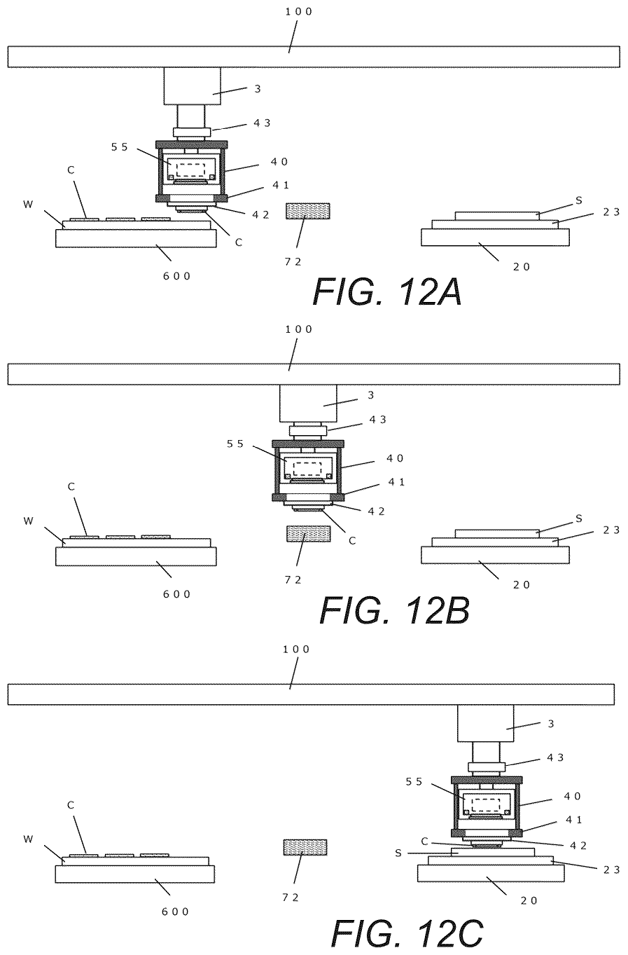

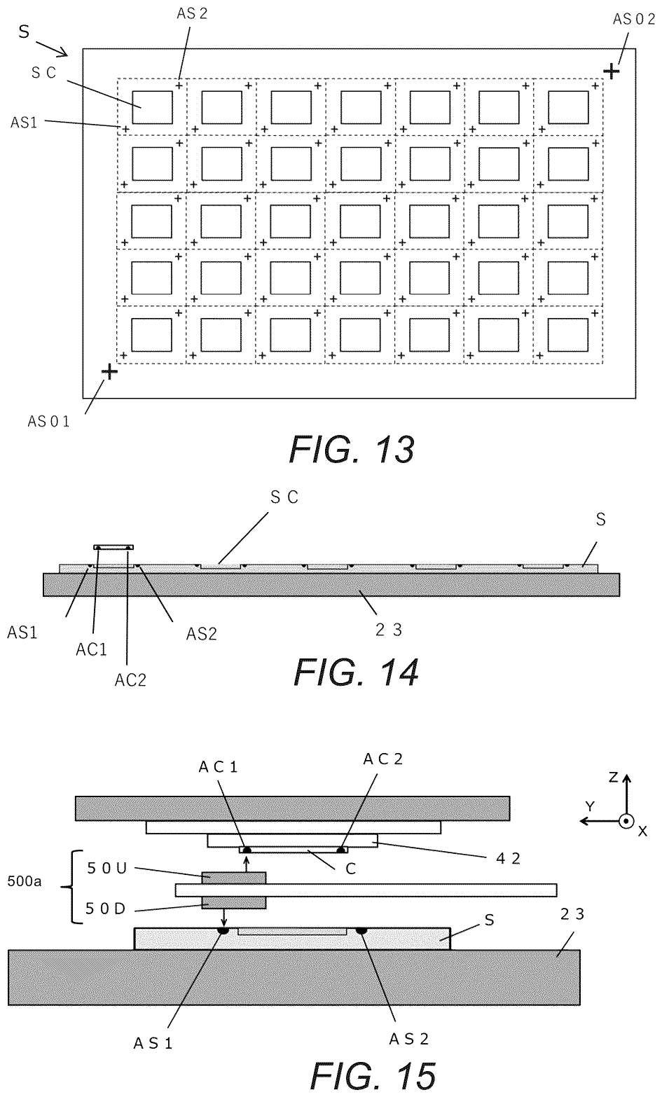

An example of the foregoing is the fifth modified example of the present embodiment shown in FIGS. 12A, 12B and 12C. In the device configuration shown in FIGS. 12A, 12B and 12C, the mounting head 4 with the head body 40, the heater unit 41, the attachment tool 42 and the tool position control means 43 picks up the chip component C from a wafer W on a stage 600, as shown in FIG. 12A. Then, the mounting head 4 moves with the elevating means 3 along a rail 100 to above the substrate stage 2 with the stage movement control means 20 and the suction table 23 (FIG. 12C) to mount the chip component C on the substrate S. With this configuration, the transmission light source 72 is disposed along the path on which the mounting head 4 moves (as shown in FIG. 12B) to acquire the position information of the chip recognition marks AC. Thereafter, position information of the substrate recognition marks AS is acquired in the state shown in FIG. 12C. With this configuration, as long as the relative position between the image capture unit 50 (FIG. 1) of the recognition means 5 and the attachment tool 42 is maintained during movement, the position information of the chip recognition marks AC and the substrate recognition marks AS can be compared as is at the same coordinates.

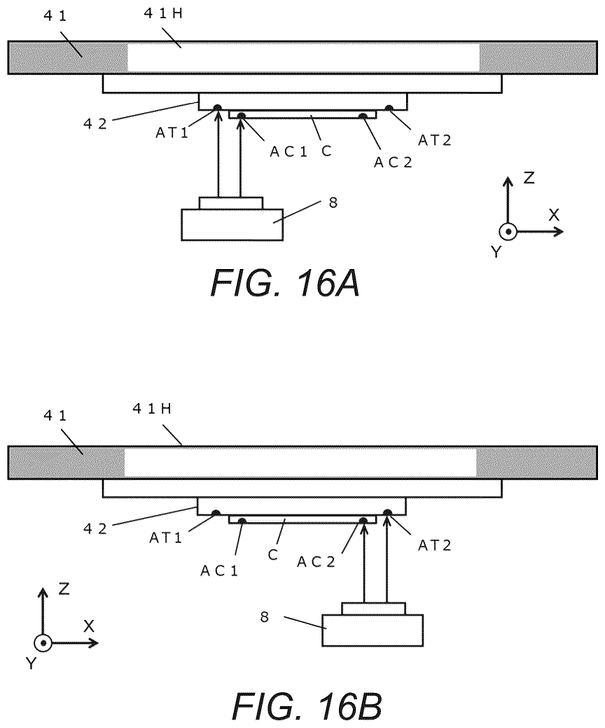

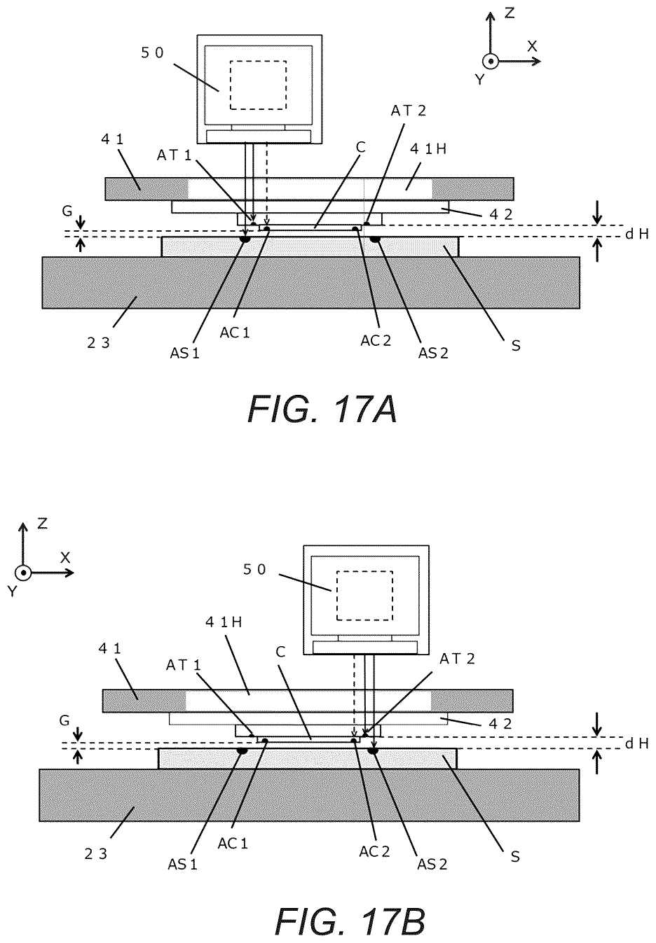

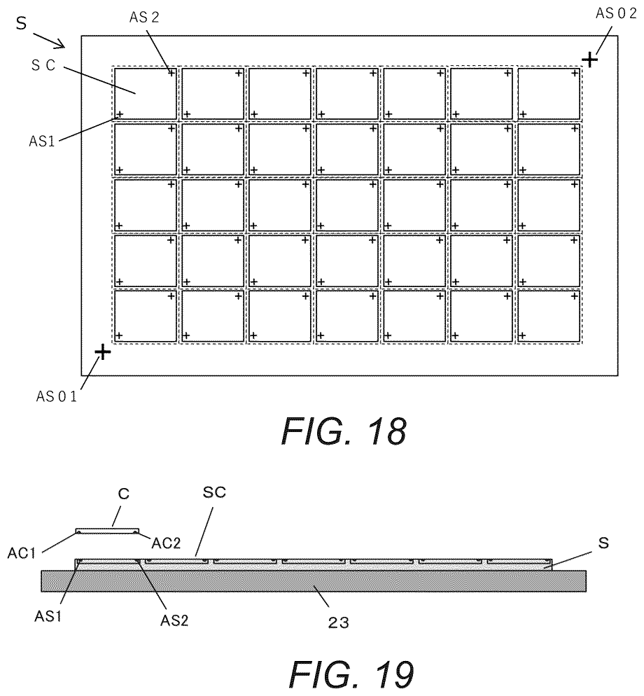

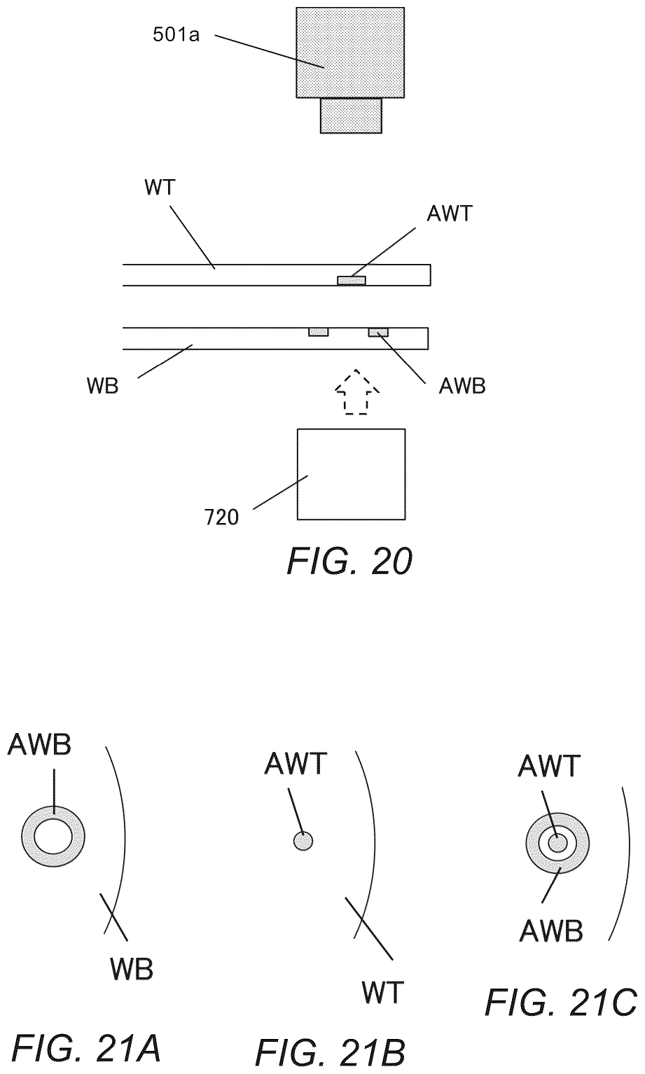

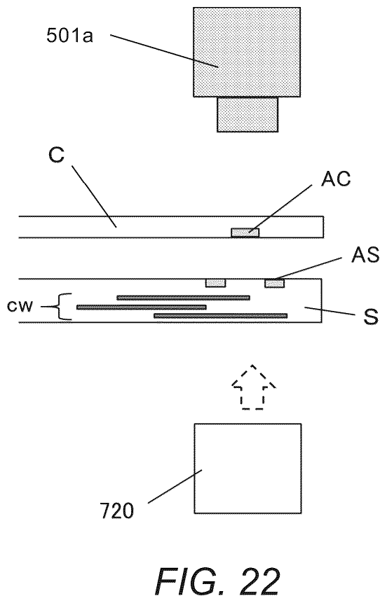

The present disclosure is particularly effective when mounting is performed in a state in which the substrate recognition marks AS are covered by the chip components C, as shown in FIG. 18, but the present disclosure is also effective when the substrate recognition marks AS are not covered by the chip components C, as shown in FIG. 13. That is, with the present disclosure, since an image of the chip recognition marks AC transmitted through the chip component C is obtained, the chip position recognition means 8 shown in FIGS. 16A and 16B becomes unnecessary.

What is claimed is:

1. A mounting device configured to mount a chip component having a chip recognition mark for alignment and a substrate having a substrate recognition mark for alignment such that a surface having the chip recognition mark faces a surface having the substrate recognition mark, in a state in which the substrate recognition mark is covered by the chip component, the mounting device comprising:
an attachment tool configured to hold a surface of the chip component opposite to the surface having the chip recognition mark;
a substrate stage configured to hold the substrate;
a reflection light source configured to irradiate light containing wavelengths that pass through the chip component from the attachment tool side toward the substrate; and
a recognition unit configured to recognize reflected light of the light irradiated by the reflection light source, the recognition unit being configured to acquire an image formed by light that passes through the chip component and is reflected by the substrate, to acquire position information of the substrate recognition mark.

2. The mounting device according to claim 1, wherein
the recognition unit is configured to acquire an image formed by light that is irradiated from the reflection light source, passes through the chip component and is reflected by the surface of the chip component having the chip recognition mark, to acquire position information of the chip recognition mark, and
the position information of the substrate recognition mark and the position information of the chip recognition mark are used to align the substrate and the chip.

3. The mounting device according to claim 1, further comprising
a transmission light source disposed below the chip component and configured to irradiate light containing wavelengths that pass through the chip component toward the chip component,
the recognition unit being configured to acquire an image formed by light that is irradiated from the transmission light source and has wavelengths that pass through the chip component, to acquire position information of the chip recognition mark, and
the position information of the substrate recognition mark and the position information of the chip recognition mark being used to align the substrate and the chip.

4. The mounting device according to claim 3, wherein
the recognition unit is configured to acquire the position information of the chip recognition mark, after which the attachment tool is moved toward the substrate stage, and
the position information of the substrate recognition mark is acquired in a state in which the chip component is brought close to the substrate such that the substrate recognition mark is within a depth of field of the recognition unit.

5. The mounting device according to claim 4, wherein
a relative position of the recognition unit with respect to the attachment tool is maintained after the position information of the chip recognition mark is acquired until the position information of the substrate recognition mark is acquired.

6. The mounting device according to claim 1, further comprising
a transmission light source configured to irradiate light containing wavelengths that pass through the chip component toward the chip component from below the chip component,
the attachment tool having a tool recognition mark,
the recognition unit being configured to acquire position information of the chip recognition mark and position information of the tool recognition mark from an image formed by light that is irradiated from the transmission light source and has wavelengths that pass through the chip component and the attachment tool, after which the recognition unit is configured to acquire position information of the substrate recognition mark and position information of the tool recognition mark from an image formed by light that is irradiated from the reflection light source and is reflected by the substrate, and has wavelengths that pass through the chip component and the attachment tool, and
relative position information with the tool recognition mark is used to obtain a positional relationship between the substrate recognition mark and the chip recognition mark, to align the substrate and the chip.

7. The mounting device according to claim 6, wherein
the position information of the substrate recognition mark and the position information of the tool recognition mark are acquired in a state in which the chip component is brought close to the substrate such that both the substrate recognition mark and the tool recognition mark are within a depth of field of the recognition unit.
